(19) United States
(12) Patent Application Publication
(10) Pub. No.: US 2024/0276824 A1
(43) Pub. Date: Aug. 15, 2024

(54) DISPLAY PANEL AND DISPLAY DEVICE

(71) Applicant: WUHAN TIANMA MICRO-ELECTRONICS CO., LTD., Wuhan (CN)

(72) Inventors: Qin YUE, Wuhan (CN); Yangzhao MA, Wuhan (CN)

(73) Assignee: WUHAN TIANMA MICRO-ELECTRONICS CO., LTD., Wuhan (CN)

(21) Appl. No.: 18/546,563

(22) PCT Filed: Aug. 31, 2022
(86) PCT No.: PCT/CN2022/116154

§ 371 Date: Aug. 15, 2023

(30) Foreign Application Priority Data
Jun. 28, 2022 (CN) 202210752015.8

(51) Int. Cl. H10K 59/35

(52) U.S. Cl. CPC H10K 59/353; H10K 59/352

(57) ABSTRACT

Display panel and Display apparatus are provided. Display panel includes: first display region and optical component installing region; and pixel units, the pixel units respectively correspond to virtual quadrilaterals, pixel unit includes one first sub-pixel and four second sub-pixels, first sub-pixel is located in virtual quadrilateral, and four second sub-pixels are respectively located at four vertexes of virtual quadrilateral; virtual quadrilateral includes first edge, second edge, third edge, and fourth edge, angle between third edge and fourth edge is first angle, and first angle is less than or equal to 90°; virtual quadrilaterals include first virtual quadrilateral in first display region and second virtual quadrilateral in optical component installing region, and first sub-pixel corresponding to the first virtual quadrilateral and first sub-pixel corresponding to second virtual quadrilateral have same color; and first angle θ1 of first virtual quadrilateral and first angle θ2 of second virtual quadrilateral satisfy θ2>θ1.

### CROSS-REFERENCE TO RELATED APPLICATIONS

The present disclosure claims priority to Chinese Patent Application No. 202210752015.8, filed on Jun. 28, 2022 and titled “DISPLAY PANEL AND DISPLAY APPARATUS”, the contents of which are incorporated herein by reference in its entirety.

### TECHNICAL FIELD

The present disclosure relates to the field of display technologies, and in particular to a display panel and a display apparatus.

### BACKGROUND

At present, an organic light emitting diode (OLED) display panel is a research hotspot in the flat panel display (FPD) field. Compared with a liquid crystal display (LCD) panel, the OLED display panel has advantages of low energy consumption, spontaneous emission, wide viewing angle and fast response speed, and has been widely applied to mobile phones, computers and other electronic devices.

However, the unmatched lifetime of sub-pixels in different regions of the existing display panel causes display unevenness and other undesirable phenomena of the display panel.

### SUMMARY

In view of this, embodiments of the present disclosure provide a display panel and a display apparatus that solve a difference in lifetime decay of sub-pixels in different regions.

According to an aspect, an embodiment of the present disclosure provides a display panel, including:
a display region including a first display region and an optical component installing region; and
pixel units (pixel cells) located in the display region, where each of the pixel units corresponds to a virtual quadrilateral, each of the pixel units includes one first sub-pixel and four second sub-pixels, and the first sub-pixel is located in the virtual quadrilateral, the four second sub-pixels are respectively located at four vertexes of the virtual quadrilateral;
the virtual quadrilateral includes a first edge, a second edge, a third edge, and a fourth edge that are connected sequentially, an angle between the third edge and the fourth edge is a first angle, and the first angle is less than or equal to 90°;
the virtual quadrilateral includes a first virtual quadrilateral and a second virtual quadrilateral, the first virtual quadrilateral is located in the first display region, the second virtual quadrilateral is located in the optical component installing region, and light emitted by the first sub-pixel corresponding to the first virtual quadrilateral and light emitted by the first sub-pixel corresponding to the second virtual quadrilateral have a same color; and
the first angle of the first virtual quadrilateral is θ1, and the first angle of the second virtual quadrilateral is θ2, wherein θ2>θ1.

According to another aspect, an embodiment of the present disclosure provides a display apparatus, including the foregoing display panel.

One of the foregoing technical solutions has following beneficial effects:

When apertures are formed in masks, apertures (apertures in different marks) corresponding to two adjacent sub-pixels of different colors or apertures (apertures in a same mask) corresponding to two adjacent sub-pixels of a same color typically overlap with each other. In this case, an overlapping portion between the apertures is subjected to corner cutting, thereby forming actually non-square apertures. Certainly, a larger corner cutting area indicates smaller areas of finally formed apertures and smaller areas of evaporated sub-pixels.

According to the embodiment of the present disclosure, the sub-pixels in the optical component installing region and the sub-pixels in the first display region are arranged differently. By increasing the first angle of the second virtual quadrilateral corresponding to the pixel cell in the optical component installing region, two second sub-pixels at vertexes of the second edge in the second virtual quadrilateral can further be pulled apart, and an overlapping amount between two apertures corresponding to the two second sub-pixels is also reduced. In this way, the corner cutting area for the apertures can be reduced, and the actual areas of the corner cut apertures can be increased. For example, the corner cut apertures tend to be a square, thereby increasing the areas of the evaporated second sub-pixels, and effectively improving the total aperture ratio of the optical component installing region.

Therefore, the embodiment of the present disclosure can effectively weaken a difference between the optical component installing region and the first display region in terms of the total aperture ratio, and slows down lifetime decay of the sub-pixels in the optical component installing region, thereby improving display evenness of the optical component installing region and the first display region.

In addition, it is further to be noted that the embodiment of the present disclosure can further optimize a spacing between anodes, while optimizing the arrangement of the sub-pixels in the optical component installing region. When external ambient light enters a camera through the optical component installing region, diffraction of the external ambient light between the anodes can be reduced. The diffraction phenomenon can be weakened obviously, thereby preventing spikes in the image and optimizing an imaging effect.

### BRIEF DESCRIPTION OF DRAWINGS

To describe the technical solutions in the embodiments of the present disclosure more clearly, the following briefly describes the accompanying drawings required to be used in the embodiments. Apparently, the accompanying drawings in the following description show merely some embodiments of the present disclosure, and a person of ordinary skill in the art may still derive other accompanying drawings from these accompanying drawings without creative efforts.

FIG. 1 is a schematic arrangement view of a sub-pixel in a prior art;

FIG. 2 is a schematic arrangement view of a sub-pixel according to an embodiment of the present disclosure:

FIG. 3 is a top view of a display panel according to an embodiment of the present disclosure:

FIG. 4 is a schematic arrangement view of a sub-pixel in a first display region according to an embodiment of the present disclosure:

FIG. 5 is a schematic arrangement view of a sub-pixel in an optical component installing region according to an embodiment of the present disclosure:

FIG. 6 is a schematic structural view of a pixel unit in a first display region and in an optical component installing region according to an embodiment of the present disclosure:

FIG. 7 is a cross-sectional partial view of a display panel according to an embodiment of the present disclosure;

FIG. 8 is a schematic positional view of an aperture and a sub-pixel in a mask according to an embodiment of the present disclosure:

FIG. 9 is a schematic view of a mask according to an embodiment of the present disclosure:

FIG. 10 is a schematic corner cutting view of an aperture in a mask according to an embodiment of the present disclosure:

FIG. 11 is a schematic view of a comparison on diffraction according to an embodiment of the present disclosure;

FIG. 12 is a schematic view of a comparison on a first color sub-pixel in a first display region and in an optical component installing region according to an embodiment of the present disclosure:

FIG. 13 is a schematic structural view of a first virtual quadrilateral and a second virtual quadrilateral according to an embodiment of the present disclosure:

FIG. 14 is another schematic structural view of a first virtual quadrilateral and a second virtual quadrilateral according to an embodiment of the present disclosure:

FIG. 15 is a schematic view of a comparison on a second sub-pixel corresponding to a first virtual quadrilateral and a second virtual quadrilateral according to an embodiment of the present disclosure:

FIG. 16 is a schematic positional view of a first sub-pixel according to an embodiment of the present disclosure:

FIG. 17 is another schematic structural view of a pixel unit in a first display region and in an optical component installing region according to an embodiment of the present disclosure.

FIG. 18 is another schematic structural view of a pixel unit in a first display region and in an optical component installing region according to an embodiment of the present disclosure:

FIG. 19 is another top view of a display panel according to an embodiment of the present disclosure:

FIG. 20 is a schematic structural view of a transition region according to an embodiment of the present disclosure:

FIG. 21 is another schematic structural view of a transition region according to an embodiment of the present disclosure;

FIG. 22 is another schematic structural view of an optical component installing region according to an embodiment of the present disclosure:

FIG. 23 is a schematic structural view of a sub-pixel in an optical component installing region according to an embodiment of the present disclosure:

FIG. 24 is another top view of a display panel according to an embodiment of the present disclosure; and

FIG. 25 is a schematic structural view of a display apparatus according to an embodiment of the present disclosure.

### DESCRIPTION OF EMBODIMENTS

For the sake of a better understanding of the technical solutions of the present disclosure, the embodiments of the present disclosure are described in detail below with reference to the accompanying drawings.

It should be noted that the embodiments in the following descriptions are only a part rather than all of the embodiments in the present disclosure. All other embodiments obtained by a person of ordinary skill in the art on the basis of the embodiments of the present disclosure shall fall within the protection scope of the present disclosure.

Terms used in the embodiments of the present disclosure are only for the purpose of describing specific embodiments, and are not intended to limit the present disclosure. Unless otherwise specified in the context, words, such as “a”, “the”, and “this”, in a singular form in the embodiments of the present invention and the appended claims include plural forms.

It should be understood that the term “and/or” in this specification merely describes associations between associated objects, and it indicates three types of relationships. For example, A and/or B may indicate that A exists alone, A and B coexist, or B exists alone. In addition, the character “/” in this specification generally indicates that the associated objects are in an “or” relationship.

At present, most sub-pixels in an OLED display panel are arranged in a “red, green, blue, and green (RGBG)” manner, a “delta” manner, and a “diamond” manner.

The “diamond” arrangement is used as an example for description.

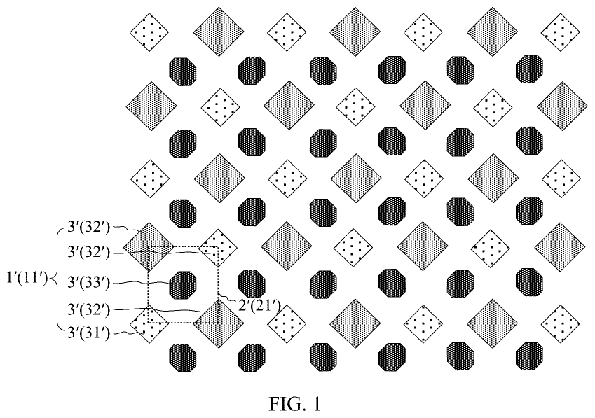

FIG. 1 is a schematic arrangement view of a sub-pixel in a prior art. As shown in FIG. 1, the display panel includes pixel units 1. Each of the pixel units 1 correspond s to one of virtual squares 2. The pixel unit 1 includes five sub-pixels 3. One sub-pixel 3 is located in the virtual square 2, and remaining four sub-pixels 3 around the sub-pixel 3 are respectively located at four vertexes of the virtual square 2. Exemplarily, referring to FIG. 1, the pixel units 1 include a first pixel unit 11. The first pixel unit 11 includes two red sub-pixels 31, two blue sub-pixels 32, and one green sub-pixel 33. The virtual squares 2 include a first virtual square 21. The green sub-pixel 33 is located in the first virtual square 21, and the two red sub-pixels 31 and the two blue sub-pixels 32 around the green sub-pixel 33 are respectively located at four vertexes of the virtual square 21.

Research shows that when the display panel displays an image based on the above arrangement, an obvious color stripe deviated from the original image occurs at an edge of the image. For example, referring to FIG. 1, when the green sub-pixel 33 is close to a lower edge of the display panel, a green stripe is evident at a lower edge of the displayed image on the display panel. Consequently, the lower edge of the display panel contains a green edge to seriously affect a display effect.

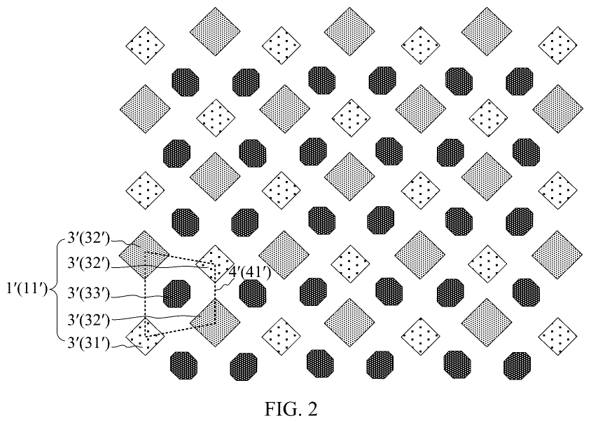

In view of this, on the basis of the “diamond” arrangement, a “Windmill” arrangement is further provided. FIG. 2 is a schematic arrangement view of a sub-pixel according to an embodiment of the present disclosure. As shown in FIG. 2, the virtual squares 2 corresponding to the pixel units 1 in FIG. 1 are adjusted as virtual trapezoids 4. For example, the virtual trapezoids 4 include a first virtual trapezoid 41. The green sub-pixel 33 is located in the first virtual trapezoid 41, and the two red sub-pixels 31 and the two blue sub-pixels 32 around the green sub-pixel 33 are respectively located at four vertexes of the first virtual trapezoid 41.

Compared with the “diamond” arrangement, positions of the sub-pixels 3 in the “Windmill” arrangement are different. For example, at a position close to the lower edge of the display panel, the red sub-pixel 31 and the blue sub-pixel 32 are staggered in a row direction, and the red sub-pixel 31 is closer to the edge of the display panel. This utilizes red light to weaken the green stripe at the lower edge, thereby effectively improving the color edge of the display panel.

For the display panel with a photographing function, a display region includes an optical component installing region for providing an optical component. At present, it is a common practice to improve a transmittance of the optical component installing region by reducing a pixel density in the optical component installing region, thus obtaining a better imaging quality. In this way, a total aperture ratio of the optical component installing region is obviously less than a total aperture ratio of the common display region. For example, according to a design, the pores per linear inch (PPI) of the common display region are 374, and the total aperture ratio of the common display region is 23.13%. The PPI of the optical component installing region is only 93, and the total aperture ratio of the optical component installing region is only about 16%.

In the above structure, if it is desired to make the optical component installing region luminous same as the common display region, a drive current flowing to the sub-pixel in the optical component installing region is to be increased. In this case, the sub-pixel in the optical component installing region has a large current density and fast lifetime decay. After a period of time, serious luminance reduction and color excursion are caused.

Therefore, by applying the “Windmill” arrangement to the display panel, the color edge can be improved, but the appearance of sub-pixels of the display panel vary a lot in lifetime, thus causing display unevenness.

In view of this, an embodiment of the present disclosure further provides a technical solution. While improving the color edge, the technical solution can further solve the display unevenness of the common display region 1 and the optical component installing region 3.

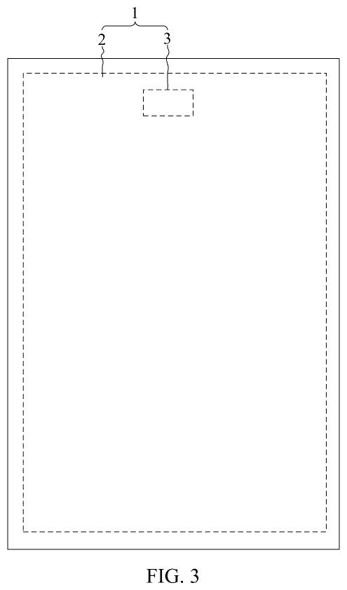

FIG. 3 is a top view of a display panel according to an embodiment of the present disclosure. As shown in FIG. 3, the display panel includes a display region 1. The display region 1 includes a first display region 2 and an optical component installing region 3. The first display region 2 is the common display region. The optical component installing region 3 is a display region for realizing photographing and other functions. The optical component installing region 3 is correspondingly provided with an optical component such as a camera, and may specifically be shaped as a square, a circle or an ellipse. In the embodiment of the present disclosure, a pixel density of the optical component installing region 3 may be less than a pixel density of the first display region 2, so as to improve a transmittance of the optical component installing region 3.

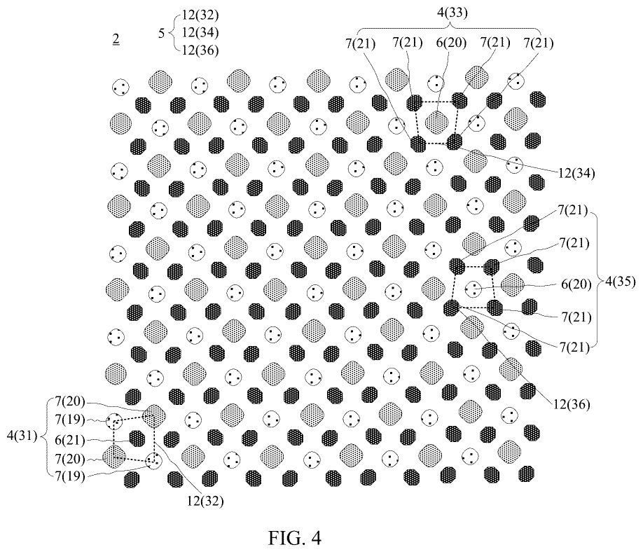

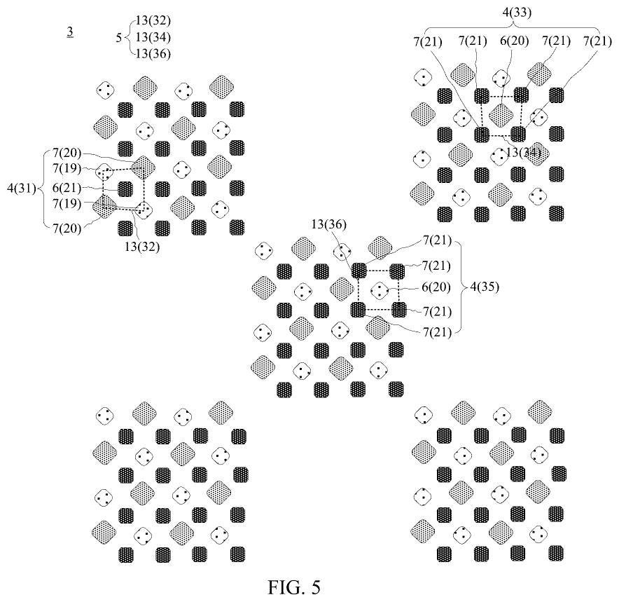

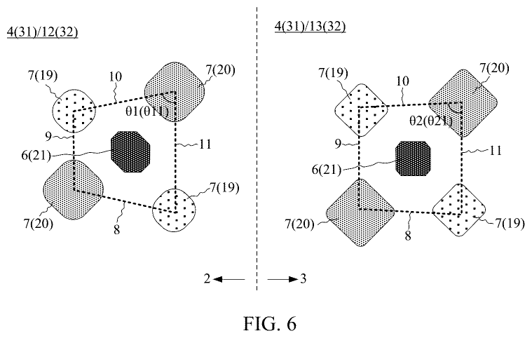

FIG. 4 is a schematic arrangement view of a sub-pixel in a first display region 2 according to an embodiment of the present disclosure. FIG. 5 is a schematic arrangement view of a sub-pixel in an optical component installing region 3 according to an embodiment of the present disclosure. FIG. 6 is a schematic structural view of a pixel unit 4 in a first display region 2 and in an optical component installing region 3 according to an embodiment of the present disclosure. As shown in FIG. 4 to FIG. 6, the display panel further includes pixel units 4 in the display region 1. Each of the pixel units 4 correspond to one of virtual quadrilaterals 5. The virtual quadrilateral 5 may specifically be a virtual trapezoid. The pixel unit 4 includes one first sub-pixel 6 and four second sub-pixels 7. The first sub-pixel 6 is located in the virtual quadrilateral 5, and the four second sub-pixels 7 are respectively located at four vertexes of the virtual quadrilateral 5. The first sub-pixel 6 and the second sub-pixel 7 emit light of different colors.

It is to be noted that when some sub-pixel is located in the virtual quadrilateral 5, this sub-pixel serves as the first sub-pixel 6 in the pixel unit 4 corresponding to the virtual quadrilateral 5. When the sub-pixel is located at a vertex of another virtual quadrilateral 5, the sub-pixel serves as the second sub-pixel 7 of the pixel unit 4 corresponding to the virtual quadrilateral 5.

The virtual quadrilateral 5 includes a first edge 8, a second edge 9, a third edge 10, and a fourth edge 11 that are connected sequentially. An angle between the third edge 10 and the fourth edge 11 is a first angle. The first angle is less than or equal to 90°.

The virtual quadrilaterals 5 include a first virtual quadrilateral 12 and a second virtual quadrilateral 13. The first virtual quadrilateral 12 is located in the first display region 2. The second virtual quadrilateral 13 is located in the optical component installing region 3. Light emitted by the first sub-pixel 6 corresponding to the first virtual quadrilateral 12 and light emitted by the first sub-pixel 6 corresponding to the second virtual quadrilateral 13 have a same color. The first angle of the first virtual quadrilateral 12 is θ1, and the first angle of the second virtual quadrilateral 13 is θ2, wherein θ2>θ1.

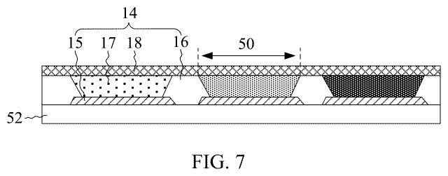

FIG. 7 is a cross-sectional partial view of a display panel according to an embodiment of the present disclosure. As shown in FIG. 7, it is to be noted that the display panel includes a substrate 52 and a light-emitting device layer 14 at one side of the substrate 52. The light-emitting device layer 14 includes anodes 15, a pixel definition layer 16, a light emission layer 17, and a cathode 18. The pixel definition layer 16 includes apertures 50. The light emission layer 17 is located in the apertures 50 of the pixel definition layer 16. In the embodiment of the present disclosure, the sub-pixels may be understood as the light emission layer 17 in the apertures 50 of the pixel definition layer 16. In the following description, positions of the sub-pixels and a spacing between the sub-pixels refer to positions of the apertures 50 and a spacing between the apertures 50 in the pixel definition layer 16. It is to be noted that an array layer may further be included between the substrate 52 and the light-emitting device layer 14 in the display panel, which is not shown in the figure.

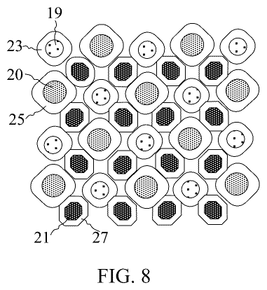

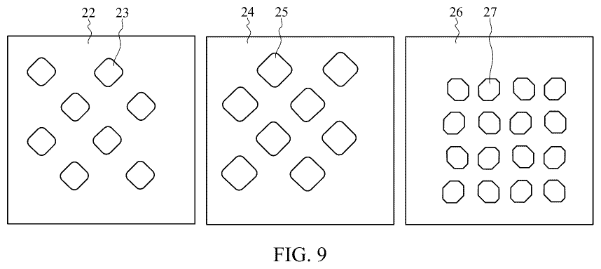

During manufacturing of the display panel, the sub-pixels are evaporated with a mask. Apertures are formed in the mask. Typically, an area of each aperture is greater than an area of each sub-pixel to be evaporated. When the display panel includes sub-pixels of different colors, sub-pixels of a same color are evaporated with a same mask. FIG. 8 is a schematic positional view of an aperture and a sub-pixel in a mask according to an embodiment of the present disclosure. FIG. 9 is a schematic view of a mask according to an embodiment of the present disclosure. As shown in FIG. 8 and FIG. 9, when the display panel includes red sub-pixels 19, blue sub-pixels 20, and green sub-pixels 21. The red sub-pixels 19 are evaporated with a first mask 22. The first mask 22 includes first apertures 23. The blue sub-pixels 20 are evaporated with a second mask 24. The second mask 24 includes second apertures 25. The green sub-pixels are evaporated with a third mask 26. The third mask 26 includes third apertures 27.

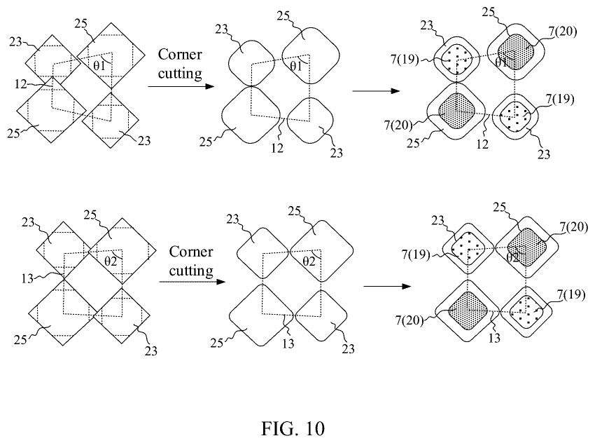

FIG. 10 is a schematic corner cutting view of an aperture in a mask according to an embodiment of the present disclosure. As shown in FIG. 10, when apertures are formed in masks, for the sake of a compact arrangement of the sub-pixels in the display panel, apertures (apertures in different marks) corresponding to two adjacent sub-pixels of different colors or apertures (apertures in a same mask) corresponding to two adjacent sub-pixels of a same color typically overlap with each other. In order to prevent color mixing and realize a compact arrangement of pixels in the display panel, an overlapping portion between the apertures is subjected to corner cutting, thereby forming actually non-square apertures. Generally, a larger corner cutting area indicates smaller areas of finally formed apertures, and smaller areas of evaporated sub-pixels.

According to the embodiment of the present disclosure, the sub-pixels in the optical component installing region 3 and the sub-pixels the first display region 2 are arranged differently. Referring to FIG. 6 and FIG. 10, by increasing the first angle of the second virtual quadrilateral 13 corresponding to the pixel unit 4 in the optical component installing region 3, two second sub-pixels 7 at vertexes of the second edge 9 in the second virtual quadrilateral 13 can further be pulled apart, and an overlapping amount between two apertures corresponding to the two second sub-pixels 7 is also reduced. In this way, the corner cutting area for the apertures can be reduced, and the actual areas of the corner cut apertures can be increased. For example, the corner cut apertures tend to be a square, thereby increasing the areas of the evaporated second sub-pixels 7, and effectively improving the total aperture ratio of the optical component installing region 3.

Therefore, the embodiment of the present disclosure can effectively weaken a difference between the optical component installing region 3 and the first display region 2 in terms of the total aperture ratio, and slows down lifetime decay of the sub-pixels in the optical component installing region 3, thereby improving display evenness of the optical component installing region 3 and the first display region 2.

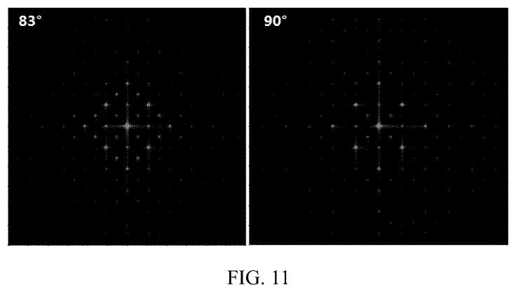

In addition, it is further to be noted that the embodiment of the present disclosure can further optimize a spacing between anodes 15, while optimizing the arrangement of the sub-pixels in the optical component installing region 3. When external ambient light enters a camera through the optical component installing region 3, diffraction of the external ambient light between the anodes 15 of the sub-pixels can be reduced. FIG. 11 is a schematic view of a comparison on diffraction according to an embodiment of the present disclosure. For example, as shown in FIG. 11, when the first angle in the second virtual quadrilateral 13 is increased to 90° from 83°, the diffraction phenomenon can be obviously weakened, thereby preventing spikes in the image, realizing bezel-less display and optimizing an imaging effect of the optical component of the display panel such as the camera.

In an embodiment, in order to ensure an appropriate distance between the five sub-pixels in the pixel unit 4 and prevent two sub-pixels from being too close and another two sub-pixels from being too far, when the θ1 and the θ2 are set, the θ1 and the θ2 satisfy: 80°≤θ1≤86°, and 83°≤θ2≤90°. This can prevent the color excursion.

In addition, a larger first angle will be favorable to increase the area of the second sub-pixel. In this case, there will be a larger aperture ratio in the pixel unit 4, and longer lifetime for the sub-pixel. Through test, as shown in Table 1, by setting the θ2 between 83° and 90°, the total aperture ratio of the optical component installing region 3 can be effectively improved.

TABLE 1

| First angle | 90° | 88° | 86° | 83° |
|---|---|---|---|---|
| Aperture ratio of the pixel unit (%) | 22.02 | 21.55 | 20.71 | 19.10 |
| Lifetime of the sub-pixel (h) | 475 | 447 | 420 | 304 |

In an embodiment, referring to FIG. 6, in the first virtual quadrilateral 12, the second edge 9 is a shortest edge. The second edge 9 in the second virtual quadrilateral 13 is longer than the second edge 9 in the first virtual quadrilateral 12.

Since the second edge 9 in the first virtual quadrilateral 12 is the shortest edge, a distance between two second sub-pixels 7 at vertexes of the second edge 9 is close, and the two second sub-pixels 7 greatly affect a corner cutting area between apertures in a mask. In view of this, in the embodiment of the present disclosure, by lengthening the second edge 9 in the second virtual quadrilateral 13, the central distance between the two second sub-pixels 7 at the vertexes of the second edge 9 can further be pulled apart. This approach better optimizes the corner cutting of the apertures, and realizes large-area sub-pixels.

In an embodiment, referring to FIG. 6, the second edge 9 is parallel to the fourth edge 11, and the third edge 10 is as long as the first edge 8 in the virtual quadrilateral 5. That is, the first virtual quadrilateral 12 and the second virtual quadrilateral 13 each are an isosceles trapezoid. In this case, the sub-pixels in the display panel are arranged more regularly to achieve a better display effect.

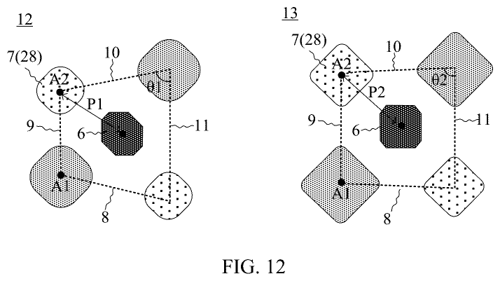

FIG. 12 is a schematic view of a comparison on a first color sub-pixel 28 in a first display region 2 and in an optical component installing region 3 according to an embodiment of the present disclosure. In an embodiment, as shown in FIG. 12, the first edge 8 is intersected with the second edge 9 at a first vertex A1, and the third edge 10 is intersected with the second edge 9 at a second vertex A2 in the virtual quadrilateral 5.

The second sub-pixel 7 at the first vertex A1 and/or the second vertex A2 in the first virtual quadrilateral 12 is a first color sub-pixel 28, and the second sub-pixel 7 at the first vertex A1 and/or the second vertex A2 in the second virtual quadrilateral 13 is the first color sub-pixel 28. The first color sub-pixel 28 corresponding to the first virtual quadrilateral 12 has an area of S1, and the first color sub-pixel 28 corresponding to the second virtual quadrilateral 13 has an area of S2, wherein S2>S1.

After the arrangement for the sub-pixels in the optical component installing region 3 is optimized, the total aperture ratio of the optical component installing region 3 can be improved by increasing the area of the first color sub-pixel 28 at the first vertex A1 and/or the second vertex A2 in the second virtual quadrilateral 13.

In an embodiment, a minimum distance between the first vertex A1 and the second vertex A2 in the first virtual quadrilateral 12 is less than a minimum distance between the first vertex A1 and the second vertex A2 in the second virtual quadrilateral 13 in the optical component installing region 3.

In an embodiment, referring also to FIG. 12, a distance between the first sub-pixel 6 and the first color sub-pixel 28 in the first virtual quadrilateral 12 is P1, and a distance between the first sub-pixel 6 and the first color sub-pixel 28 in the second virtual quadrilateral 13 is P2, wherein P2>P1.

For the optical component installing region 3, after the area of the first color sub-pixel 28 is increased, by lengthening the distance between the first sub-pixel 6 and the first color sub-pixel 28, the first sub-pixel 6 and the first color sub-pixel 28 are not too close. This prevents a luminous material in evaporation from scattering to the apertures in the adjacent pixel definition layer to cause color mixing or color excursion.

Referring to FIG. 12, it is to be noted that the distance between the above two sub-pixels may be understood as a distance between geometric centers of the two sub-pixels. It is to be understood that a pattern evaporated actually with the sub-pixel may be an irregular pattern such as a rounded rectangle. In this case, the geometric center of the sub-pixel may be a geometric center obtained by completing the irregular pattern as a regular pattern. For example, if the sub-pixel is shaped as the rounded rectangle, the geometric center of the sub-pixel is a geometric center by completing the rounded rectangle as a rectangle. Or, the distance between the two sub-pixels may also be understood as a maximum distance between edges of the two sub-pixels.

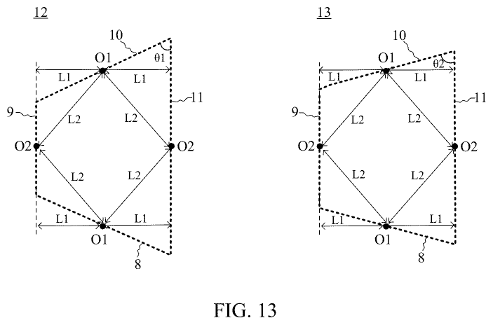

FIG. 13 is a schematic structural view of a first virtual quadrilateral 12 and a second virtual quadrilateral 13 according to an embodiment of the present disclosure. In an embodiment, as shown in FIG. 13, in the virtual quadrilateral 5, a center point at each of the first edge 8 and the third edge 10 is a first center point O1, and a center point at each of the second edge 9 and the fourth edge 11 is a second center point O2.

In the first virtual quadrilateral 12 and the second virtual quadrilateral 13, a vertical distance from the first center point O1 to the second edge 9 and a vertical distance from the first center point O1 to the fourth edge 11 each are L1, and a distance from the first center point O1 to the second center point O2 is L2. In other words, two first center points O1 and two second center points O2 in the second virtual quadrilateral 13 are translated overall to coincide with two first center points O1 and two second center points O2 in the first virtual quadrilateral 12.

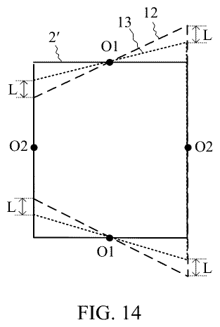

FIG. 14 is another schematic structural view of a first virtual quadrilateral 12 and a second virtual quadrilateral 13 according to an embodiment of the present disclosure. With reference to the above description on the “diamond” arrangement, in the embodiment of the present disclosure, as shown in FIG. 14, the first virtual quadrilateral 12 may be constructed on the basis of the virtual square 2 in the “diamond” arrangement. For example, while a position of a center point at each edge in the virtual square 2 is unchanged, adjustment is made on two opposite edges of the virtual square 2 to form the isosceles-trapezoid-like first virtual quadrilateral 12, and positions of the sub-pixels in the first display region 2 are slightly deviated from positions of the sub-pixels in the “diamond” arrangement. This improves the color edge without affecting the overall arrangement. In this case, center points of four edges in the first virtual quadrilateral 12 coincide with center points of four edges in the virtual square 2.

When the first angle of the second virtual quadrilateral 13 is adjusted through the positions of the corresponding second sub-pixels 7 in the second virtual quadrilateral 13, the above design concept is also applicable to the positions of the corresponding second sub-pixels 7 in the second virtual quadrilateral 13. That is, no matter how the four second sub-pixels 7 at the vertexes of the second virtual quadrilateral 13 change, the center points of the four edges in the second virtual quadrilateral 13 coincide with the center points of the four edges in the virtual square, namely the center points of the four edges in the second virtual quadrilateral 13 coincide with the center points of the four edges in the first virtual quadrilateral 12. Therefore, the arrangement of the sub-pixels in the optical component installing region 3 and the arrangement of the sub-pixels in the first display region 2 follow the same design concept. While the total aperture ratio of the optical component installing region 3 is improved, all sub-pixels of the display panel are arranged more regularly.

Referring also to FIG. 14, it is to be noted that when the second virtual quadrilateral 13 is translated, and the center points of the four edges in the second virtual quadrilateral 13 coincide with the center points of the four edges in the first virtual quadrilateral 12, a distance between any vertex in the second virtual quadrilateral 13 and any vertex in the nearest first virtual quadrilateral 12 is L.

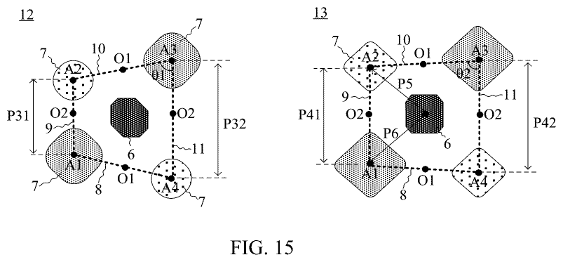

FIG. 15 is a schematic view of a comparison on a second sub-pixel 7 corresponding to a first virtual quadrilateral 12 and a second virtual quadrilateral 13 according to an embodiment of the present disclosure. In an embodiment, as shown in FIG. 15, the first edge 8 is intersected with the second edge 9 at a first vertex A1, the second edge 9 is intersected with the third edge 10 at a second vertex A2, the third edge 10 is intersected with the fourth edge 11 at a third vertex A3, and the fourth edge 11 is inserted with the first edge 8 at a fourth vertex A4 in the virtual quadrilateral 5.

In the first virtual quadrilateral 12, a distance between the second sub-pixel 7 at the first vertex A1 and the second sub-pixel 7 at the second vertex A2 is P31, and a distance between the second sub-pixel 7 at the third vertex A3 and the second sub-pixel 7 at the fourth vertex A4 is P32. It may also be understood that the second edge 9 has a length of P31, and the fourth edge 11 has a length of P32 in the first virtual quadrilateral 12. In the second virtual quadrilateral 13, a distance between the second sub-pixel 7 at the first vertex A1 and the second sub-pixel 7 at the second vertex A2 is P41, and a distance between the second sub-pixel 7 at the third vertex A3 and the second sub-pixel 7 at the fourth vertex A4 is P42. It may also be understood that the second edge 9 has a length of P41, and the fourth edge 11 has a length of P42 in the second virtual quadrilateral 13, wherein P41>P31 and P42<P32.

Compared with the first virtual quadrilateral 12, the two second sub-pixels 7 at the vertexes of the second edge 9 in the second virtual quadrilateral 13 are moved away from each other, and the two second sub-pixels 7 at the vertexes of the fourth edge 11 are moved close to each other. Thus, the two center points and the two second center points O2 in the second virtual quadrilateral 13 can be better translated overall to coincide with the two first center points O1 and the two second center points O2 in the first virtual quadrilateral 12. This better realizes the design concept on the second virtual quadrilateral 13.

Further, referring also to FIG. 15, in the second virtual quadrilateral 13, a distance between the first sub-pixel 6 and the second sub-pixel 7 at the first vertex A1 is P5, and a distance between the first sub-pixel 6 and the second sub-pixel 7 at the second vertex A2 is P6, P5=P6. In this case, distances from the first sub-pixel 6 to the two second sub-pixels 7 at the vertexes of the second edge 9 in the second virtual quadrilateral 13 are the same. Particularly when the two second sub-pixels 7 at the vertexes of the second edge 9 are sub-pixels of different colors, the first sub-pixel 6 is spaced apart from the two second sub-pixels 7 of the different colors at a same distance, thereby preventing the color excursion.

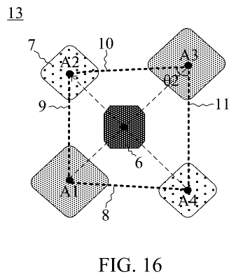

FIG. 16 is a schematic positional view of a first sub-pixel 6 according to an embodiment of the present disclosure. In an embodiment, as shown in FIG. 16, in the second virtual quadrilateral 13, a geometric center of the first sub-pixel 6 coincides with a center point of a diagonal of the virtual quadrilateral 5. In this case, the first sub-pixel 6 is located at a central position of the virtual quadrilateral 5. With the isosceles-trapezoid-like virtual quadrilateral 5 as an example, distances from the first sub-pixel 6 to the two second sub-pixels 7 at the first vertex A1 and the second vertex A2 are the same, and distances from the first sub-pixel 6 to the second sub-pixels 7 at the third vertex A3 and the fourth vertex A4 are also the same. A positional relationship between the first sub-pixel 6 and each of the sub-pixels at the four vertexes of the virtual quadrilateral is considered, such that the color excursion can be prevented to a greater extent.

In an embodiment, referring to FIG. 4 to FIG. 6, the pixel units 4 include a first pixel unit 31. The first pixel unit 31 corresponds to a first type virtual quadrilateral 32. In the first pixel unit 31, the first sub-pixel 6 is a green sub-pixel 21, two of the second sub-pixels 7 are red sub-pixels 19, and two of the second sub-pixels 7 are blue sub-pixels 20. The two red sub-pixels 19 are located at two vertexes on a diagonal in the first type virtual quadrilateral 32. The two blue sub-pixels 20 are located at two vertexes on another diagonal in the first type virtual quadrilateral 32. The first angle θ11 of the first type virtual quadrilateral 32 in the first display region 2 and the first angle θ21 of the first type virtual quadrilateral 32 in the optical component installing region 3 satisfy θ21>θ11.

In this case, by adjusting the first angle of the first type virtual quadrilateral 32 in the optical component installing region 3, a distance between the red sub-pixel 19 and the blue sub-pixel 20 at vertexes of the second edge 9 in the first type virtual quadrilateral 32 can be increased. When apertures are formed in the first mask 22 and the second mask 24, a corner cutting area for apertures corresponding to the sub-pixels can be reduced, thereby increasing areas of the evaporated red sub-pixel 19 and blue sub-pixel 20, and improving the total aperture ratio of the optical component installing region 3.

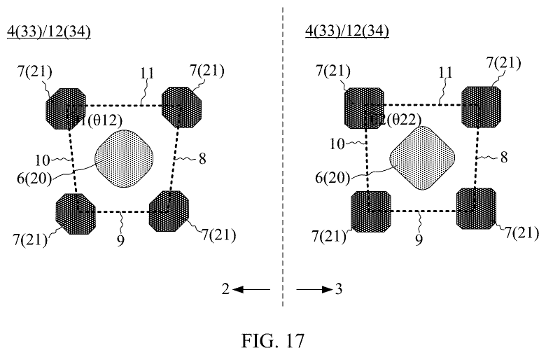

FIG. 17 is another schematic structural view of a pixel unit 4 in a first display region 2 and in an optical component installing region 3 according to an embodiment of the present disclosure. In an embodiment, referring to FIG. 4 and FIG. 5, as shown in FIG. 17, the pixel units 4 include a second pixel unit 33. The second pixel unit 33 corresponds to a second type virtual quadrilateral 34. In the second pixel unit 33, the first sub-pixel 6 is a blue sub-pixel 20, and the four second sub-pixels 7 are green sub-pixels 21. The first angle θ12 of the second type virtual quadrilateral 34 in the first display region 2 and the first angle θ22 of the second type virtual quadrilateral 34 in the optical component installing region 3 satisfy θ22>θ12.

In this case, by adjusting the first angle of the second type virtual quadrilateral 34 in the optical component installing region 3, a distance between two green sub-pixels 21 at vertexes of the second edge 9 in the second type virtual quadrilateral 34 can be increased. When apertures are formed in the third mask 26, a corner cutting area for apertures corresponding to the sub-pixels can be reduced, thereby increasing areas of the evaporated green sub-pixels 21 without sacrificing an evaporation yield, and improving the total aperture ratio of the optical component installing region 3.

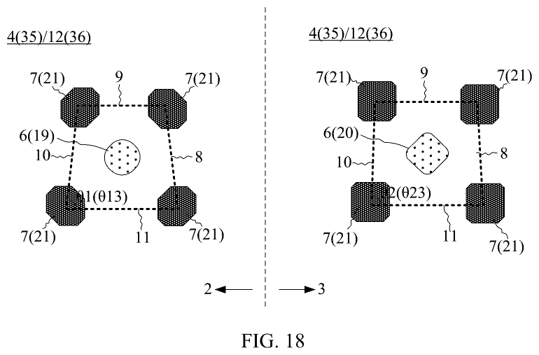

FIG. 18 is another schematic structural view of a pixel unit 4 in a first display region 2 and in an optical component installing region 3 according to an embodiment of the present disclosure. In an embodiment, referring to FIG. 4 and FIG. 5, as shown in FIG. 18, the pixel units 4 include a third pixel unit 35. The third pixel unit 35 corresponds to a third type virtual quadrilateral 36. In the third pixel unit 35, the first sub-pixel 6 is a red sub-pixel 19, and the four second sub-pixels 7 are green sub-pixels 21. The first angle θ13 of the third type virtual quadrilateral 36 in the first display region 2, and the first angle θ23 of the third type virtual quadrilateral 36 in the optical component installing region 3 satisfy θ23>θ13.

In this case, by adjusting the first angle of the third type virtual quadrilateral 36 in the optical component installing region 3, a distance between two green sub-pixels 21 at vertexes of the second edge 9 in the third type virtual quadrilateral 36 can be increased. When apertures are formed in the third mask 26, a corner cutting area for apertures corresponding to the sub-pixels can be reduced, thereby increasing areas of the evaporated green sub-pixels 21, and improving the total aperture ratio of the optical component installing region 3.

In an embodiment, in a plurality of the virtual quadrilaterals 5, the virtual quadrilaterals 5 corresponding to the first sub-pixel 6 that emits light of a same color belong to a same type of the virtual quadrilaterals 5. The same type of the virtual quadrilaterals 5 in the first display region 2 have the same first angle, and/or, the same type of the virtual quadrilaterals 5 in the optical component installing region 3 have the same first angle.

Specifically, in the first display region 2, a plurality of the first type virtual quadrilaterals 32 have the same first angle, a plurality of the second type virtual quadrilaterals 34 have the same first angle, and a plurality of the third type virtual quadrilaterals 36 have the same first angle. In the optical component installing region 3, a plurality of the first type virtual quadrilaterals 32 have the same first angle, a plurality of the second type virtual quadrilaterals 34 have the same first angle, and a plurality of the third type virtual quadrilaterals 36 have the same first angle. This improves the arrangement regularity and display effect of the sub-pixels.

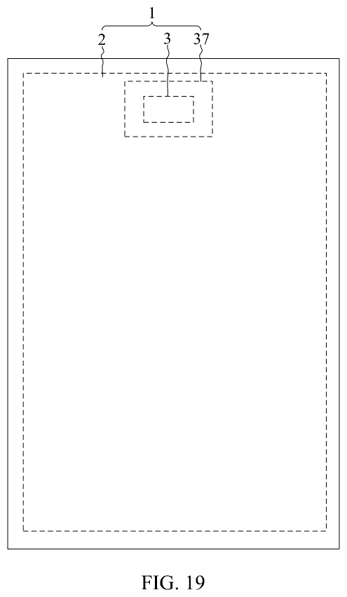

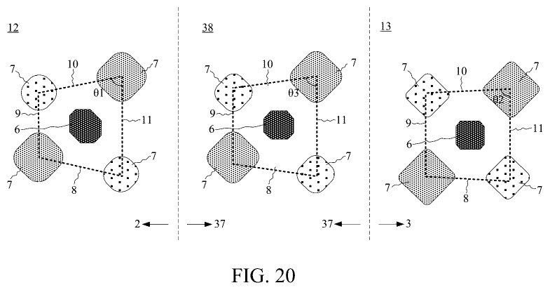

FIG. 19 is another top view of a display panel according to an embodiment of the present disclosure. FIG. 20 is a schematic structural view of a transition region 37 according to an embodiment of the present disclosure. In an embodiment, as shown in FIG. 19 and FIG. 20, the display region 1 further includes a transition region 37 around the optical component installing region. The virtual quadrilaterals 5 further include a third virtual quadrilateral 38. The third virtual quadrilateral 38 is located in the transition region 37. A color of light emitted by the first sub-pixel 6 corresponding to the third virtual quadrilateral 38 is the same as the color of the light emitted by the first sub-pixel 6 corresponding to the first virtual quadrilateral 12. The first angle of the third virtual quadrilateral 38 is θ3, θ1<θ3<θ2.

The first angle of the third virtual quadrilateral 38 in the transition region 37 is greater than the first angle of the first virtual quadrilateral 12 in the first display region 2, and less than the first angle of the second virtual quadrilateral 13 in the optical component installing region 3. For sub-pixels of a same color, this facilitates transition of areas of the sub-pixels in the first display region 2, the transition region 37 and the optical component installing region 3, such that the sub-pixels in the whole display region 1 are uniform in lifetime decay and the color excursion of a local region is prevented.

In an embodiment, 2°≤θ3−θ1≤5°, and 2°≤θ2−θ3≤5°.

If a difference between the θ3 and the θ1 and a difference between the θ2 and the θ3 are too small, there are little differences in arrangement and area for the sub-pixels in the first display region 2, the transition region 37 and the optical component installing region 3. Consequently, a desirable transition effect of the transition region 37 is hardly achieved. If the difference between the θ3 and the θ1 and the difference between the θ2 and the θ3 are too large, there is a large difference between the θ1 and the θ2. In this case, the sub-pixels in the first display region 2 and in the optical component installing region 3 vary a lot in terms of the arrangement, thus affecting the display effect.

In view of this, by setting θ3−θ1 and θ2−θ3 between 2° and 5°, the sub-pixels in the first display region 2 and in the optical component installing region 3 can be arranged optimally, and the display difference between the first display region 2 and the optical component installing region 3 can further be better weakened with the transition region 37. For the sake of more smooth transition, θ3−θ1=θ2−θ3.

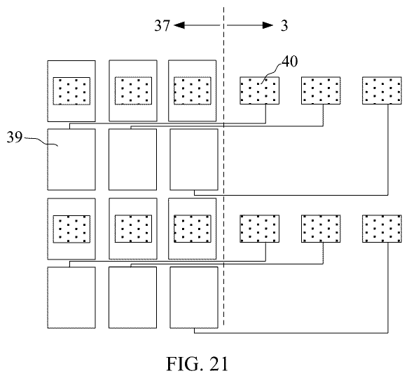

It is to be noted that the display panel further includes pixel circuits electrically connected to sub-pixels. FIG. 21 is another schematic structural view of a transition region 37 according to an embodiment of the present disclosure. In an embodiment, as shown in FIG. 21, the transition region 37 includes a first pixel circuit 39. The first pixel circuit 39 is electrically connected to a sub-pixel 40 in the optical component installing region 3. In other words, at least one of the pixel circuits electrically connected to the sub-pixel 40 in the optical component installing region 3 is provided in the transition region 37. Therefore, a number of pixel circuits to be provided in the optical component installing region 3 can be reduced, or even pixel circuits in the optical component installing region 3 turn out to be unnecessary. This increases a transmittance of the optical component installing region 3 to the greater extent, and optimizes the imaging quality.

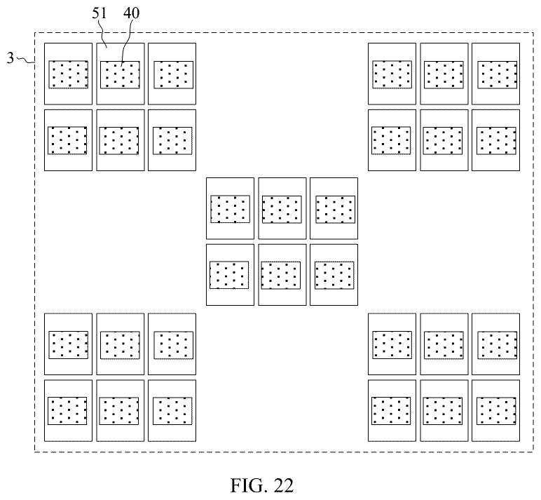

FIG. 22 is another schematic structural view of an optical component installing region 3 according to an embodiment of the present disclosure. Alternatively, In an embodiment, as shown in FIG. 22, the optical component installing region 3 includes a second pixel circuit 51. The second pixel circuit 51 is electrically connected to the sub-pixel 40 in the optical component installing region 3. In other words, the pixel circuit electrically connected to the sub-pixel 40 in the optical component installing region 3 is directly provided in the optical component installing region 3. In this case, a connecting distance between the sub-pixel 40 and the second pixel circuit 51 can be reduced, thereby reducing signal attenuation in transmission.

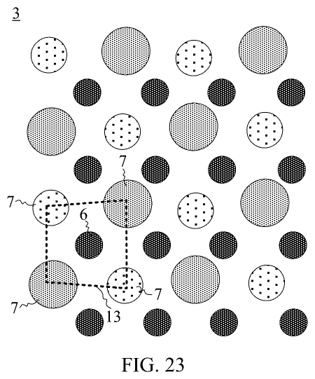

FIG. 23 is a schematic structural view of a sub-pixel in an optical component installing region 3 according to an embodiment of the present disclosure. In an embodiment, as shown in FIG. 23, in the pixel unit 4 of the optical component installing region 3, the first sub-pixel 6 and the second sub-pixel 7 are circular. Compared with the square sub-pixels, the circular sub-pixels in the optical component installing region 3 can prevent a regular stripe gap between the anodes 15 corresponding to the sub-pixels. This effectively improves the diffraction in entry of the external ambient light from the optical component installing region 3, and prevents the spikes in imaging.

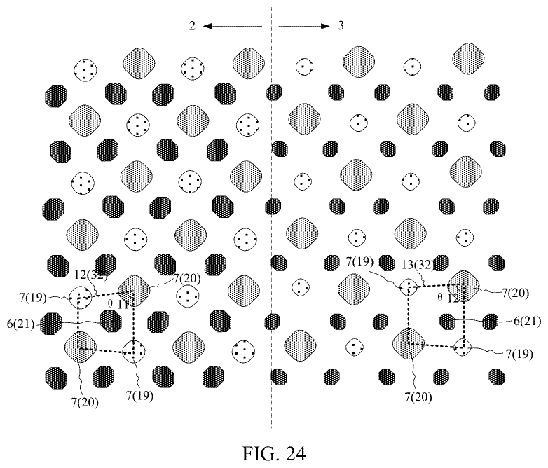

FIG. 24 is another top view of a display panel according to an embodiment of the present disclosure. In other optional implementation of the present disclosure, as shown in FIG. 24, it is to be noted that a pixel density in the optical component installing region 3 may be the same as a pixel density in the first display region 2 to improve the display effect of the optical component installing region 3. In this case, to improve the transmittance of the optical component installing region 3, an area of a single sub-pixel in the optical component installing region 3 can be reduced.

The arrangement of the sub-pixels in the optical component installing region 3 can still be optimized more reasonably by adjusting the first angle θ12 of the second virtual quadrilateral 13 in the optical component installing region 3. This reserves a part of the space for the sub-pixel with the most serious luminance decay, increases the area of the sub-pixel, and improves display lifetime of the sub-pixel. Exemplarily, compared with the first type virtual quadrilateral 32 in the first display region 2, the first angle of the first type virtual quadrilateral 32 in the optical component installing region 3 can be increased to provide a larger setting space for the blue sub-pixel 20. While the setting area of the blue sub-pixel 20 is increased to some extent, the lifetime decay rate of the blue sub-pixel 20 is reduced, and the blue sub-pixel 20 is more consistent with the red sub-pixel 19 and the green sub-pixel 21 in lifetime.

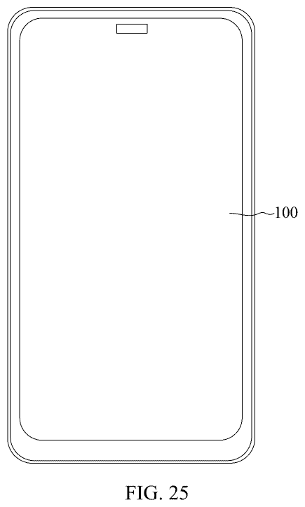

Based on a same inventive concept, an embodiment of the present disclosure provides a display apparatus. FIG. 25 is a schematic structural diagram of a display apparatus according to an embodiment of the present disclosure. As shown in FIG. 25, the display apparatus includes the above display panel 100. A specific structure of the display panel 100 has been described in detail in the foregoing embodiments, so details are not described herein again. Certainly, the display apparatus shown in FIG. 25 is for schematic description only. The display apparatus may be any electronic device with a display function, such as a mobile phone, a tablet computer, a notebook computer, an e-book, or a television.

The above descriptions are merely preferred embodiments of the present disclosure, and are not intended to limit the present disclosure. Any modifications, equivalent replacements, improvements, and the like made within the spirit and principle of the present disclosure shall fall within the protection scope of the present disclosure.

Finally, it should be noted that the above embodiments are merely intended to describe the technical solutions of the present disclosure, rather than to limit the present disclosure. Although the present disclosure is described in detail with reference to the above embodiments, persons of ordinary skill in the art should understand that they may still make modifications to the technical solutions described in the above embodiments or make equivalent replacements to some or all technical features thereof, without departing from the essence of the technical solutions in the embodiments of the present disclosure.

What is claimed is:

1. A display panel, comprising:
a display region comprising a first display region and an optical component installing region; and
pixel units located in the display region, wherein each of the pixel units corresponds to a virtual quadrilateral, each of the pixel units comprises one first sub-pixel and four second sub-pixels, and the first sub-pixel is located in the virtual quadrilateral, the four second sub-pixels are respectively located at four vertexes of the virtual quadrilateral;
wherein the virtual quadrilateral comprises a first edge, a second edge, a third edge, and a fourth edge that are connected sequentially, a first angle between the third edge and the fourth edge is less than or equal to 90°;
the virtual quadrilateral comprises a first virtual quadrilateral and a second virtual quadrilateral, the first virtual quadrilateral is located in the first display region, the second virtual quadrilateral is located in the optical component installing region, and light emitted by the first sub-pixel corresponding to the first virtual quadrilateral has a same color as light emitted by the first sub-pixel corresponding to the second virtual quadrilateral; and
a first angle θ1 of the first virtual quadrilateral and a first angle θ2 of the second virtual quadrilateral satisfy θ2>θ1.

2. The display panel according to claim 1, wherein
80°≤θ1≤86°, and 83°≤θ2≤90°.

3. The display panel according to claim 1, wherein
the second edge is a shortest edge in the first virtual quadrilateral; and
the second edge in the second virtual quadrilateral is longer than the second edge in the first virtual quadrilateral.

4. The display panel according to claim 1, wherein
the second edge is parallel to the fourth edge, and the third edge has a same length as the first edge.

5. The display panel according to claim 1, wherein
the first edge is intersected with the second edge at a first vertex, and the second edge is intersected with the third edge at a second vertex;
a second sub-pixel of the four second sub-pixels at the first vertex and/or the second vertex in the first virtual quadrilateral is a first color sub-pixel, and a second sub-pixel of the four second sub-pixels at the first vertex and/or the second vertex in the second virtual quadrilateral is the first color sub-pixel; and
an area S1 of the first color sub-pixel corresponding to the first virtual quadrilateral and an area S2 of the first color sub-pixel corresponding to the second virtual quadrilateral satisfy S2>S1.

6. The display panel according to claim 5, wherein
a distance P1 between the first sub-pixel and the first color sub-pixel in the first virtual quadrilateral and a distance P2 between the first sub-pixel and the first color sub-pixel in the second virtual quadrilateral satisfy P2>P1.

7. The display panel according to claim 1, wherein
a center point at each of the first edge and the third edge is a first center point, and a center point at each of the second edge and the fourth edge is a second center point; and
in the first virtual quadrilateral and the second virtual quadrilateral, a vertical distance from the first center point to the second edge and a vertical distance from the first center point to the fourth edge each are both L1, and a distance from the first center point to the second center point is L2.

8. The display panel according to claim 1, wherein
the first edge is intersected with the second edge at a first vertex, the second edge is intersected with the third edge at a second vertex, the third edge is intersected with the fourth edge at a third vertex, and the fourth edge is intersected with the first edge at a fourth vertex;
in the first virtual quadrilateral, a distance between the second sub-pixel at the first vertex and the second sub-pixel at the second vertex is P31, and a distance between the second sub-pixel at the third vertex and the second sub-pixel at the fourth vertex is P32; and
in the second virtual quadrilateral, a distance P41 between the second sub-pixel at the first vertex and the second sub-pixel at the second vertex and a distance P42 between the second sub-pixel at the third vertex and the second sub-pixel at the fourth vertex satisfy P41>P31 and P42<P32.

9. The display panel according to claim 8, wherein
in the second virtual quadrilateral, a distance P5 between the first sub-pixel and the second sub-pixel at the first vertex and a distance P6 between the first sub-pixel and the second sub-pixel at the second vertex satisfy P5=P6.

10. The display panel according to claim 1, wherein
in the second virtual quadrilateral, a geometric center of the first sub-pixel coincides with a center point of a diagonal of the virtual quadrilateral.

11. The display panel according to claim 1, wherein
the pixel units comprise a first pixel unit: the first pixel unit corresponds to a first type virtual quadrilateral; and in the first pixel unit, the first sub-pixel is a green sub-pixel, two of the second sub-pixels are red sub-pixels, and two of the second sub-pixels are blue sub-pixels;
wherein the two red sub-pixels are located at two vertexes on a diagonal in the first type virtual quadrilateral; and the two blue sub-pixels are located at two vertexes on another diagonal in the first type virtual quadrilateral; and
a first angle θ11 of the first type virtual quadrilateral in the first display region and a first angle θ21 of the first type virtual quadrilateral in the optical component installing region satisfy θ21>θ11.

12. The display panel according to claim 1, wherein
the pixel units comprise a second pixel unit, the second pixel unit corresponds to a second type virtual quadrilateral, and in the second pixel unit, the first sub-pixel is a blue sub-pixel, and the four second sub-pixels are green sub-pixels; and
a first angle θ12 of the second type virtual quadrilateral in the first display region and a first angle θ22 of the second type virtual quadrilateral in the optical component installing region satisfy θ22>θ12.

13. The display panel according to claim 1, wherein
the pixel units comprise a third pixel unit, the third pixel unit corresponds to a third type virtual quadrilateral, and in the third pixel unit, the first sub-pixel is a red sub-pixel, and the four second sub-pixels are green sub-pixels; and
a first angle θ13 of the third type virtual quadrilateral in the first display region and a first angle θ23 of the third type virtual quadrilateral in the optical component installing region satisfy θ23>θ13.

14. The display panel according to claim 1, wherein
for a plurality of virtual quadrilaterals, the virtual quadrilaterals corresponding to the first sub-pixel that emits light of a same color belong to a same type of the virtual quadrilaterals; and
the same type of the virtual quadrilaterals in the first display region have the same first angle, and/or, the same type of the virtual quadrilaterals in the optical component installing region have the same first angle.

15. The display panel according to claim 1, wherein
the display region further comprises a transition region around the optical component installing region; and
the virtual quadrilaterals further comprise a third virtual quadrilateral, and the third virtual quadrilateral is located in the transition region, a color of light emitted by the first sub-pixel corresponding to the third virtual quadrilateral is the same as the color of light emitted by the first sub-pixel corresponding to the first virtual quadrilateral,
wherein a first angle θ3 of the third virtual quadrilateral satisfy θ1<θ3<θ2.

16. The display panel according to claim 15, wherein
2°≤θ3−θ1≤5°, and 2°≤θ2−θ3≤5°.

17. The display panel according to claim 15, wherein
θ3−θ1=θ2−θ3.

18. The display panel according to claim 15, wherein
the transition region comprises a first pixel circuit, and the first pixel circuit is electrically connected to a sub-pixel in the optical component installing region.

19. The display panel according to claim 1, wherein
in the pixel units located in the optical component installing region, the first sub-pixel and the second sub-pixel are circular.

20. A display apparatus, comprising the display panel according to any one of claims 1 to 19.
